(19) United States
(12) Patent Application Publication
(10) Pub. No.: US 2025/0318108 A1
(43) Pub. Date: Oct. 9, 2025

(54) SEMICONDUCTOR STRUCTURE AND METHODS OF FORMING THE SAME

(71) Applicant: NANYA TECHNOLOGY CORPORATION, New Taipei city (TW)

(72) Inventor: Chen-Hao LIEN, New Taipei City (TW)

(21) Appl. No.: 18/626,512

(22) Filed: Apr. 4, 2024

(51) Int. Cl. H10B 12/00; H01L 21/3205; H01L 21/321; H01L 21/3215

(52) U.S. Cl. CPC H10B 12/482; H01L 21/32055; H01L 21/32105; H01L 21/3215

(57) ABSTRACT

The present disclosure provides a method of forming a semiconductor structure. The method includes the following operations. A silicon-containing conductive layer is formed between bitline structures. A first portion of the silicon-containing conductive layer is transformed into an oxide layer under an ozone environment. A nitride layer is formed on the oxide layer and the bitline structures. A portion of the nitride layer on the oxide layer and a portion of the oxide layer disposed below the portion of the nitride layer are removed. A conductive layer is formed on a second portion of the silicon-containing conductive layer after removing the portion of the oxide layer.

### BACKGROUND

### Field of Invention

The present disclosure relates to a semiconductor structure and methods of forming the same.

### Description of Related Art

A memory device, such as dynamic random-access memory, includes bitline structures to write and read information stored in the memory cell. To have high writing and reading speed, the electrical resistance between the conducting parts of the device should be small enough. For example, the electrical resistance of a contact structure disposed beside the bitline structure to electrically connect the capacitor of the memory cell should be small. However, while forming the contact structure, too much doped conductive impurity in the contact structure may influence the roughness of the contact structure, thereby generating the unwanted void in the contact structure to increase the electrical resistance. Decreasing the conductive impurity doped in the contact structure, on the other hand, may cause the electrical resistance of the formed contact structure to have an unacceptably high value since the conductive impurity may diffuse outside the contact structure during the formation of the contact structure. Therefore, it is necessary to develop new, easy, low-cost methods of forming the contact structure having small electrical resistance.

### SUMMARY

The present disclosure provides a method of forming a semiconductor structure. The method includes the following operations. A silicon-containing conductive layer is formed between bitline structures. A first portion of the silicon-containing conductive layer is transformed into an oxide layer under an ozone environment. A nitride layer is formed on the oxide layer and the bitline structures. A portion of the nitride layer on the oxide layer and a portion of the oxide layer disposed below the portion of the nitride layer are removed. A conductive layer is formed on a second portion of the silicon-containing conductive layer after removing the portion of the oxide layer.

In some embodiments, after transforming the first portion of the silicon-containing conductive layer into the oxide layer under the ozone environment, a thickness of the oxide layer is smaller than 1.5 nm.

In some embodiments, the oxide layer separates the second portion of the silicon-containing conductive layer from the nitride layer.

In some embodiments, transforming the first portion of the silicon-containing conductive layer into the oxide layer under the ozone environment is performed in an ozone gas with a flow rate from 100 g/cm³ to 200 g/cm³.

In some embodiments, transforming the first portion of the silicon-containing conductive layer into the oxide layer under the ozone environment is performed at a temperature from 250° C. to 300° C.

In some embodiments, transforming the first portion of the silicon-containing conductive layer into the oxide layer under the ozone environment is performed with a processed time from 20 minutes to 30 minutes.

In some embodiments, forming the nitride layer is performed at a temperature from 550° C. to 650° C.

In some embodiments, the method further includes doping a P-type dopant or an N-type dopant into the silicon-containing conductive layer before transforming the first portion of the silicon-containing conductive layer into the oxide layer.

In some embodiments, after forming the nitride layer, a dopant concentration in the silicon-containing conductive layer is from 7.5×10²⁰ atoms/cm³ to 7.5×10²¹ atoms/cm³.

The present disclosure also provides a method of forming a semiconductor structure. The method includes the following operations. A first conductive layer is formed next to a bitline structure, in which the first conductive layer includes a P-type impurity or an N-type impurity. An upper portion of the first conductive layer is reacted with an oxidizing agent to transform the upper portion into an oxide layer. A nitride layer is formed on the oxide layer and the bitline structure. A portion of the nitride layer on the oxide layer and a portion of the oxide layer disposed below the portion of the nitride layer are removed. A second conductive layer in direct contact with a lower portion of the first conductive layer is formed.

In some embodiments, after reacting the upper portion of the first conductive layer with the oxidizing agent to transform the upper portion into the oxide layer, a thickness of the oxide layer is smaller than 1.5 nm.

In some embodiments, the oxidizing agent includes H₂O₂.

In some embodiments, reacting the upper portion of the first conductive layer with the oxidizing agent is performed with a reaction time from 60 seconds to 100 seconds.

In some embodiments, forming the nitride layer is performed at a temperature from 550° C. to 650° C.

In some embodiments, after forming the nitride layer, a concentration of the P-type impurity or the N-type impurity in the first conductive layer is from 7.5×10²⁰ atoms/cm³ to 7.5×10²¹ atoms/cm³.

The present disclosure also provides a semiconductor structure. The semiconductor structure includes a substrate, bitline structures, a polysilicon layer, a metal layer, a silicon oxide layer, and a nitride layer. The bitline structures are on the substrate. The polysilicon layer is between the bitline structures. The metal layer is on the polysilicon layer and between the bitline structures. The silicon oxide layer is on the polysilicon layer and between the metal layer and sidewalls of the bitline structures. The nitride layer is on the silicon oxide layer and between the metal layer and the sidewalls of the bitline structures.

In some embodiments, the silicon oxide layer separates the polysilicon layer from the nitride layer.

In some embodiments, a width of the nitride layer is substantially the same as a width of the silicon oxide layer.

In some embodiments, the polysilicon layer includes a P-type dopant or an N-type dopant, a dopant concentration of the P-type dopant is from 7.5×10²⁰ atoms/cm³ to 7.5×10²¹ atoms/cm³, and a dopant concentration of the N-type dopant is from 7.5×10²⁰ atoms/cm³ to 7.5×10²¹ atoms/cm³.

In some embodiments, a thickness of the silicon oxide layer is smaller than 1.5 nm.

### BRIEF DESCRIPTION OF THE DRAWINGS

The present disclosure can be more fully understood by reading the following detailed description of the embodiments, with reference made to the accompanying figures as follows.

FIG. 1 is a flow chart of a method of forming a semiconductor structure according to some embodiments of the present disclosure.

FIGS. 2 to 8 are cross-sectional views of the structures during the formation of the semiconductor structure according to some embodiments of the present disclosure.

FIG. 9 is a flow chart of a method of forming a semiconductor structure according to some embodiments of the present disclosure.

FIG. 10 is a diagram of an impurity concentration changing with the depth in the silicon-containing conductive layer according to an embodiment of the present disclosure.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated at 90 degrees), and the spatially relative terms can be interpreted accordingly. In the present disclosure, unless otherwise indicated, the same element numbers in different figures refer to the same or similar elements formed from the same or similar materials by the same or similar methods.

The terms “around”, “approximately”, “nearly”, “basically”, “substantially”, etc., used in the present disclosure include the stated values (or characteristics) and a deviation of the stated values (or characteristics) understood by one skilled in the art. For example, considering the errors of the values (or characteristics), these terms may indicate the values within one or more standard deviations (e.g., the values within ±30%, ±20%, ±15%, ±10%, or ±5%), or may indicate the characteristics including the deviation from the practical operation (e.g., the “substantially parallel” may indicate close to parallel in practical, rather than a perfect ideally parallelism). Furthermore, it is possible to select an acceptable range of the deviation according to the nature of the measurement or other properties, instead of applying only one single deviation range to all the values (or characteristics).

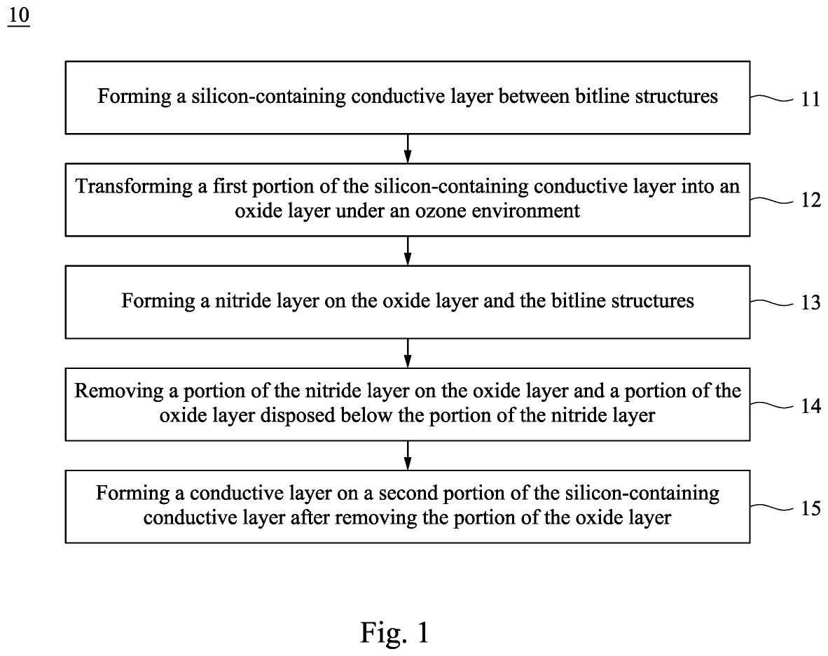

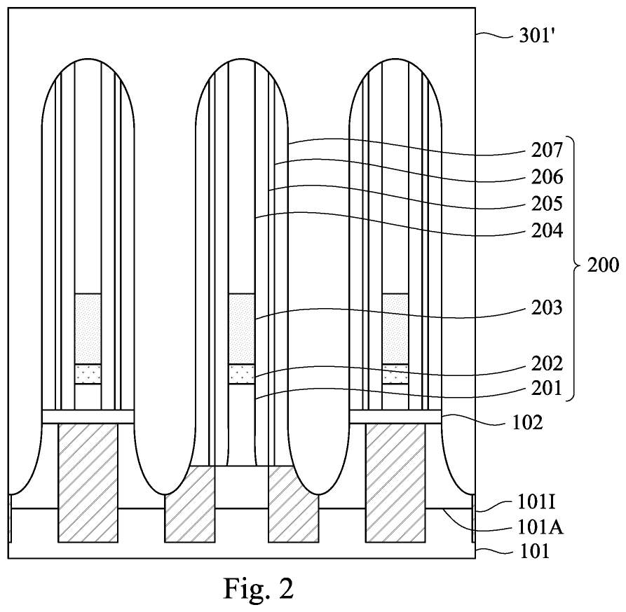

The present disclosure provides a method 10 of forming a semiconductor structure, as shown in the flow chart of FIG. 1 and further referring to FIGS. 2 to 8. The method 10 includes the following operation 11 to operation 15. The operation 11 includes forming a silicon-containing conductive layer 301 between bitline structures 200. The operation 12 includes transforming a first portion 301A of the silicon-containing conductive layer 301 into an oxide layer 301O under an ozone environment. The operation 13 includes forming a nitride layer 302 on the oxide layer 301O and the bitline structures 200. The operation 14 includes removing a portion of the nitride layer 302 on the oxide layer 301O and a portion of the oxide layer 301O disposed below the portion of the nitride layer 302. The operation 15 includes forming a conductive layer 303 on a second portion 301B of the silicon-containing conductive layer 301 after removing the portion of the oxide layer 301O. In some embodiments, the semiconductor structure formed by the method 10 is used in a memory device, such as a dynamic random-access memory, in which the formed second portion 301B of the silicon-containing conductive layer 301 has an improved low electrical resistance to be a conductive contact structure that electrically connects the capacitor of the memory cell of the memory device. The method 10 is described in detail according to some embodiments of the following disclosure.

Before performing the operation 11 to form the silicon-containing conductive layer 301 between the bitline structures 200, the method 10 further includes forming the bitline structures 200 on a substrate 101, as shown in FIG. 2. In some embodiments, the substrate 101 includes active regions 101A separated from each other by isolation regions 101I. The isolation regions 101I provide electrical isolation between the active regions 101A. In some embodiments, the substrate 101 is a semiconductor substrate and includes a semiconductor material. In some embodiments, the semiconductor material includes an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, boron nitride, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof. In some embodiments, the active regions 101A include an N-type dopant or a P-type dopant and the active regions 101A may be source/drain regions of transistors not drawn in the figures. In some embodiments, the isolation regions 101I include a dielectric material.

In some embodiments, a dielectric layer 102 is disposed on the substrate 101 to provide electrical isolation between portions of the bitline structures 200 and the active regions 101A. For example, FIG. 2 shows the cross-sections of two bitline structures 200 on the left and the right of FIG. 2 separated from the active regions 101A by the dielectric layer 102, even though these two bitline structures 200 contact the active regions 101A from the cross-sections not shown in FIG. 2. Similarly, the one bitline structure 200 in the center of FIG. 2 contacts the active regions 101A, even though this one bitline structure 200 in the center of FIG. 2 separates from the active regions 101A by the dielectric layer 102 in the cross-section not shown in FIG. 2. In some embodiments, the bitline structures 200 are disposed on the dielectric layer 102 and on the substrate 101.

In some embodiments, the number of the bitline structures 200 is not limited and the bitline structures 200 may be arranged into a two-dimensional array on the substrate 101. In some embodiments, each one of the bitline structures 200 includes a silicon-containing conductive layer 201 contacting the active regions 101A and a metal layer 203 disposed on the silicon-containing conductive layer 201. The silicon-containing conductive layer 201 and the metal layer 203 conduct the electrical current for data writing and reading in the bitline structures 200. In some embodiments, the silicon-containing conductive layer 201 includes polysilicon. In some embodiments, the metal layer 203 includes tungsten, titanium, tantalum, ruthenium, iridium, platinum, rhodium, molybdenum, aluminum, copper, or the like, in which tungsten is preferable for having low electrical resistance and low contact resistance.

In some embodiments, each one of the bitline structures 200 further includes a metal-containing layer 202 disposed between the silicon-containing conductive layer 201 and the metal layer 203 to reduce the electrical resistance between the silicon-containing conductive layer 201 and the metal layer 203 and to provide a better adhesion between the silicon-containing conductive layer 201 and the metal layer 203. In some embodiments, the metal-containing layer 202 includes titanium nitride. In some embodiments, each one of the bitline structures 200 further includes a dielectric layer 204 on the metal layer 203 to provide electrical isolation for the bitline structures 200 and to be used as a hard mask layer when forming the bitline structures 200. In some embodiments, the dielectric layer 204 includes silicon nitride.

In some embodiments, each one of the bitline structures 200 further includes an inner spacer 205 on sidewalls of the bitline structures 200, an outer spacer 207 on the inner spacer 205, and an intermediate spacer 206 between the inner spacer 205 and the outer spacer 207. The inner spacer 205, the intermediate spacer 206, and the outer spacer 207 provide electrical isolation for the bitline structures 200 and may be used as a manufacturing tolerance to provide a space for the N-type dopant or the P-type dopant in the active regions 101A to diffuse in the substrate 101. Therefore, the manufacturing tolerance can avoid the current leakage between the adjacent bitline structures 200 owing to the diffusion of the N-type dopant or the P-type dopant. In some embodiments, the inner spacer 205 and the outer spacer 207 respectively includes silicon nitride. In some embodiments, the intermediate spacer 206 includes silicon dioxide or preferably air to reduce parasitic capacitance.

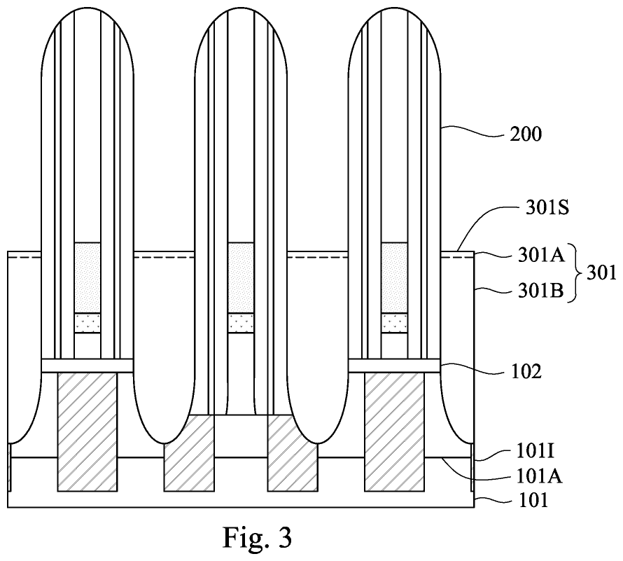

The operation 11 includes forming the silicon-containing conductive layer 301 between the bitline structures 200, as shown in FIGS. 2 and 3. In some embodiments, the silicon-containing conductive layer 301 is used as the conductive contact structure in the memory device to electrically connect the capacitor (not drawn in the figures) of the memory cell. In some embodiments, forming the silicon-containing conductive layer 301 includes depositing a material 301′ of the silicon-containing conductive layer 301 between the bitline structures 200 by any suitable deposition method and etching portions of the material 301′ of the silicon-containing conductive layer 301 to form the silicon-containing conductive layer 301 by any suitable etching method. In some embodiments, the suitable deposition method includes a chemical vapor deposition or a physical vapor deposition. In some embodiments, the suitable etching method includes a dry etching or a wet etching. In some embodiments, the material 301′ of the silicon-containing conductive layer 301 is polysilicon. In some embodiments, when forming the silicon-containing conductive layer 301 between the bitline structures 200, upper surfaces of the bitline structures 200 are rounded for a better deposition of the material 301′ of the silicon-containing conductive layer 301. In some embodiments, the silicon-containing conductive layer 301 contacts the active regions 101A.

In some embodiments, the method 10 further includes doping a P-type dopant or an N-type dopant into the silicon-containing conductive layer 301 to increase the conductivity of the silicon-containing conductive layer 301 before performing the operation 12 to transform the first portion 301A of the silicon-containing conductive layer 301 into the oxide layer 301O. In some embodiments, the P-type dopant includes boron, aluminum, or the like. In some embodiments, the N-type dopant includes phosphorus, antimony, arsenic, or the like. In some embodiments, doping the P-type dopant or the N-type dopant is performed by in-situ doping during the deposition of the material 301′ of the silicon-containing conductive layer 301. In some embodiments, a dopant concentration of the P-type dopant or the N-type dopant is preferably from 7.5×10²⁰ atoms/cm³ to 7.5×10²¹ atoms/cm³, for example, 7.5×10²⁰ atoms/cm³, 1.0×10²¹ atoms/cm³, 2.5×10²¹ atoms/cm³, 5.0×10²¹ atoms/cm³, or 7.5×10²¹ atoms/cm³. Too many dopants in the silicon-containing conductive layer 301 may increase the roughness of the silicon-containing conductive layer 301 and generate voids that increase the electrical resistance of the silicon-containing conductive layer 301. Too few dopants in the silicon-containing conductive layer 301 may increase the electrical resistance of the silicon-containing conductive layer 301. In some embodiments, the foregoing dopant concentration is obtained by measuring the dopant concentration in the region of the silicon-containing conductive layer 301 from the topmost surface 301S of the silicon-containing conductive layer 301 to a depth of around 20 nm.

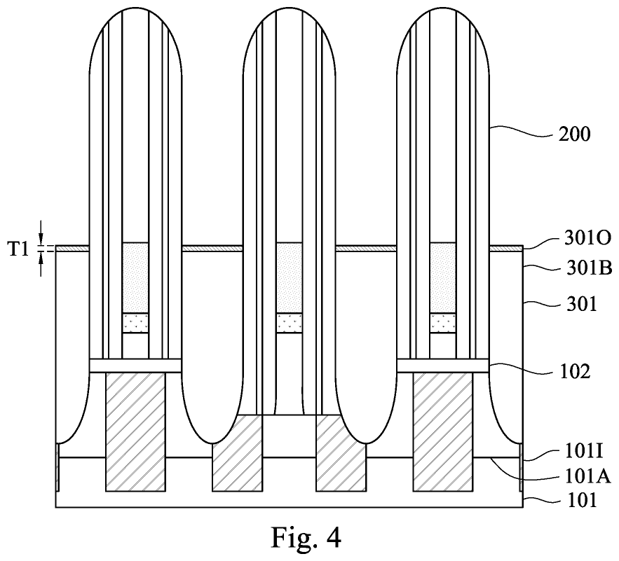

The operation 12 includes transforming the first portion 301A of the silicon-containing conductive layer 301 into the oxide layer 301O under the ozone environment, as shown in FIGS. 3 and 4. The formed oxide layer 301O prevents the conductive impurity (e.g., the P-type dopant or the N-type dopant) in the silicon-containing conductive layer 301 from migrating from the silicon-containing conductive layer 301 to the outside structure in the following operations. Therefore, the P-type dopant or the N-type dopant doped in the silicon-containing conductive layer 301 is not necessary to be too high to increase the roughness of the silicon-containing conductive layer 301, and enough P-type dopant or N-type dopant remains in the silicon-containing conductive layer 301 after the following operations to reduce the electrical resistance of the silicon-containing conductive layer 301. In some embodiments, the first portion 301A of the silicon-containing conductive layer 301 is an exposed surface portion of the silicon-containing conductive layer 301. In some embodiments, after transforming the first portion 301A of the silicon-containing conductive layer 301 into the oxide layer 301O under the ozone environment, the first portion 301A is oxidized and the second portion 301B of the silicon-containing conductive layer 301 disposed below the first portion 301A remains unoxidized. In some embodiments, the first portion 301A of the silicon-containing conductive layer 301 includes silicon oxide. In some embodiments, a thickness T1 of the oxide layer 301O is preferably smaller than 1.5 nm. In some embodiments, the thickness T1 of the oxide layer 301O is preferably from 0.5 nm to 1.5 nm, for example, 0.5 nm, 0.75 nm, 1.0 nm, 1.25 nm, or 1.5 nm. When the thickness T1 is too thick, too much P-type dopant or N-type dopant may be oxidized in the silicon-containing conductive layer 301 to decrease the conductivity of the silicon-containing conductive layer 301. When the thickness T1 is too thin, the oxide layer 301O may not effectively prevent the P-type dopant or the N-type dopant from migrating from the silicon-containing conductive layer 301 to the outside structure.

In some embodiments, transforming the first portion 301A of the silicon-containing conductive layer 301 into the oxide layer 301O under the ozone environment is performed in an ozone gas with a flow rate preferably from 100 g/cm³ to 200 g/cm³, for example, 100 g/cm³, 125 g/cm³, 150 g/cm³, 175 g/cm³, or 200 g/cm³, to obtain a desirable thickness T1 of the oxide layer 301O. In some embodiments, transforming the first portion 301A of the silicon-containing conductive layer 301 into the oxide layer 301O under the ozone environment is performed at a temperature preferably from 250° C. to 300° C., for example, 250° C., 275° C., or 300° C., to obtain a desirable thickness T1 of the oxide layer 301O effectively in a desirable time. In some embodiments, transforming the first portion 301A of the silicon-containing conductive layer 301 into the oxide layer 301O is not performed by using plasma, since the energy of the plasma may be too high to fail to form the silicon-containing conductive layer 301 with a desirable thickness T1 that is small enough. In some embodiments, transforming the first portion 301A of the silicon-containing conductive layer 301 into the oxide layer 301O under the ozone environment is performed with a processed time preferably from 20 minutes to 30 minutes, for example, 20 minutes, 25 minutes, or 30 minutes, to obtain a desirable thickness T1 of the oxide layer 301O effectively in a desirable time.

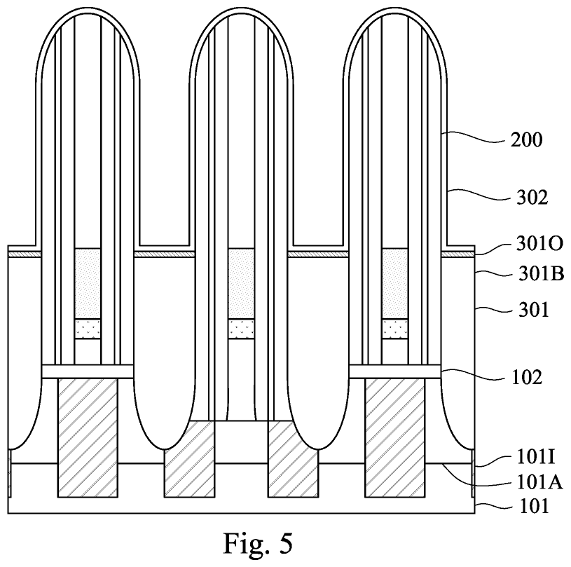

The operation 13 includes forming the nitride layer 302 on the oxide layer 301O and the bitline structures 200, as shown in FIG. 5. The nitride layer 302 provides electrical isolation for the bitline structures 200 and may enclose the air inside the intermediate spacer 206. In some embodiments, the nitride layer 302 includes silicon nitride. In some embodiments, forming the nitride layer 302 is performed at a temperature from 550° C. to 650° C., for example, 550° C., 575° C., 600° C., 625° C., or 650° C., to improve the quality of the nitride layer 302. When forming the nitride layer 302 at the temperature from 550° C. to 650° C., the impurity (e.g., the P-type dopant or the N-type dopant) in the silicon-containing conductive layer 301 is blocked by the oxide layer 301O from migrating from the silicon-containing conductive layer 301 to the outside structure. Without having the oxide layer 301O, the impurity in the silicon-containing conductive layer 301 may migrate from the silicon-containing conductive layer 301 to the nitride layer 302 when forming the nitride layer 302. Therefore, the impurity concentration of the silicon-containing conductive layer 301 before forming the nitride layer 302 is substantially the same as the impurity concentration of the silicon-containing conductive layer 301 after forming the nitride layer 302. In some embodiments, the segregation of coefficient of the impurity in the silicon-containing conductive layer 301 to migrate to the nitride layer 302 is smaller than 1. In some embodiments, the nitride layer 302 is conformally formed on the oxide layer 301O and the bitline structures 200.

In some embodiments, the dopant concentration of the P-type dopant or the N-type dopant remaining in the silicon-containing conductive layer 301 after forming the nitride layer 302 is from 7.5×10²⁰ atoms/cm³ to 7.5×10²¹ atoms/cm³, for example, 7.5×10²⁰ atoms/cm³, 1.0×10²¹ atoms/cm³, 2.5×10²¹ atoms/cm³, 5.0×10²¹ atoms/cm³, or 7.5×10²¹ atoms/cm³. In other words, the dopant concentration is not only not too high to increase the roughness of the silicon-containing conductive layer 301 but also remains enough after forming the nitride layer 302 to decrease the electrical resistance of the silicon-containing conductive layer 301. In some embodiments, the foregoing dopant concentration is obtained by measuring the dopant concentration from the topmost surface of the second portion 301B to a depth of around 20 nm. In some embodiments, the oxide layer 301O separates the second portion 301B of the silicon-containing conductive layer 301 from the nitride layer 302. In some embodiments, the oxide layer 301O contacts the nitride layer 302.

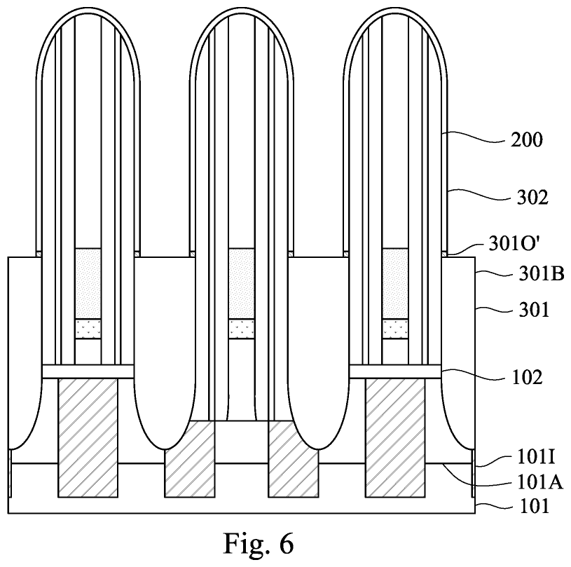

The operation 14 includes removing a portion of the nitride layer 302 disposed on the oxide layer 301O and a portion of the oxide layer 301O disposed under the portion of the nitride layer 302 that is removed, as shown in FIGS. 5 and 6. After the operation 14, a portion of the upper surface of the silicon-containing conductive layer 301 is exposed and the exposed portion will contact the conductive layer 303 formed on the silicon-containing conductive layer 301 in the following operation 15. In some embodiments, the operation 14 is performed by any suitable etching method, for example, a dry etching.

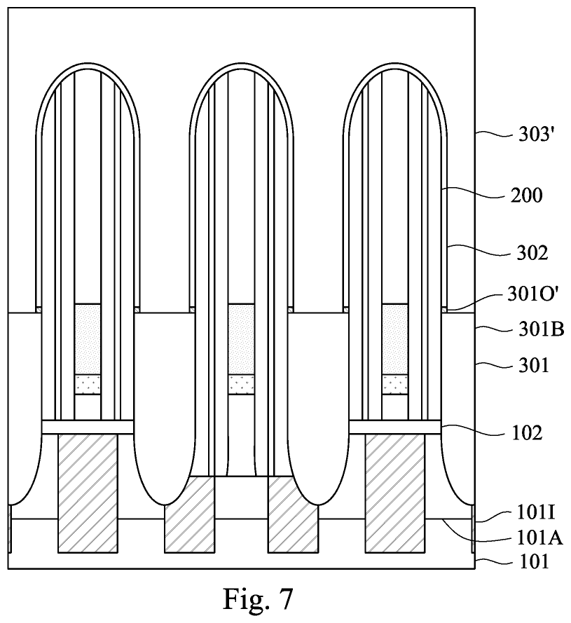

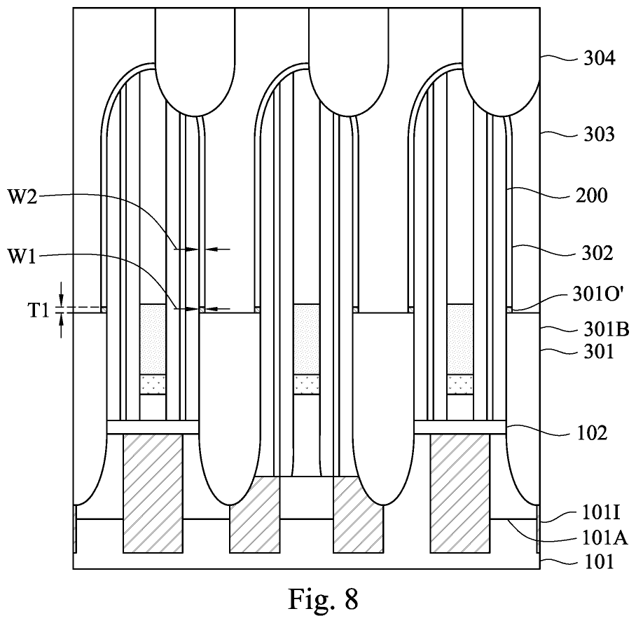

The operation 15 includes forming the conductive layer 303 on the silicon-containing conductive layer 301 after removing the portion of the oxide layer 301O, as shown in FIGS. 7 and 8. In some embodiments, the conductive layer 303 and the silicon-containing conductive layer 301 are used as the conductive contact structure in the memory device to electrically connect the capacitor (not drawn in the figures) of the memory cell. In some embodiments, the capacitor (not drawn in the figures) may be disposed on the conductive layer 303. In some embodiments, forming the conductive layer 303 includes depositing a material 303′ of the conductive layer 303 on the silicon-containing conductive layer 301 by any suitable deposition method and etching portions of the material 303′ of the conductive layer 303 to form openings by any suitable etching method, in which the openings are later filled with a dielectric layer 304 as shown in FIG. 8. Therefore, the conductive layer 303 includes separated portions respectively disposed on the silicon-containing conductive layer 301 as shown in FIG. 8. In some embodiments, the material 303′ of the conductive layer 303 is a metal, for example, tungsten. In some embodiments, the suitable deposition method includes a chemical vapor deposition or a physical vapor deposition. In some embodiments, the suitable etching method includes a dry etching.

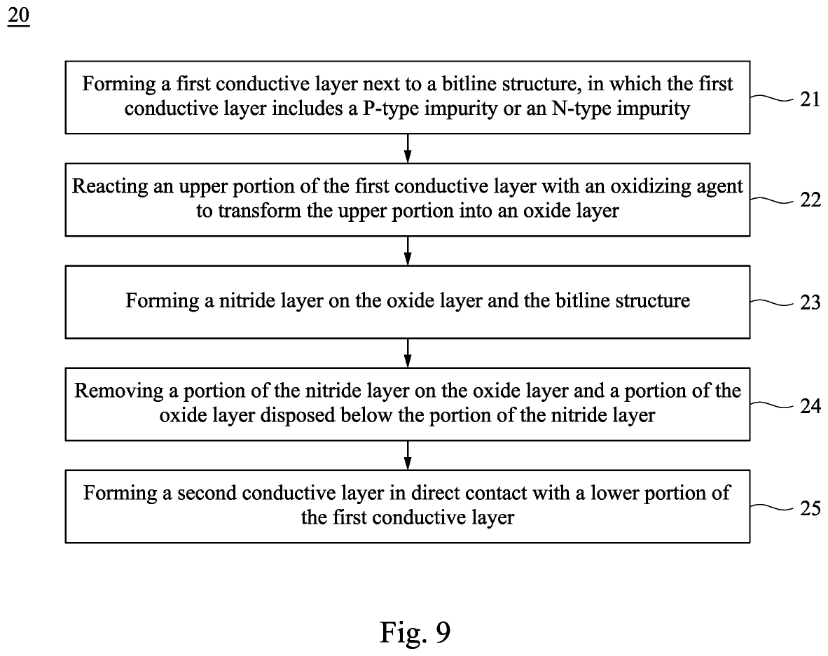

The present disclosure also provides a method 20 of forming a semiconductor structure, as shown in the flow chart of FIG. 9. The method includes operation 21 to operation 25. The method 20 is similar to the method 10 described above, except that the oxidation process of forming the oxide layer 301O is different. Therefore, for a detailed description of the method 20, please refer to the method 10, and FIGS. 2 to 8 are applicable to describe the method 20.

The operation 21 of the method 20 is similar to the operation 11 of the method 10, in which a first conductive layer (i.e., the silicon-containing conductive layer 301 described above) including a P-type impurity (i.e., the P-type dopant described above) or an N-type impurity (i.e., the N-type dopant described above) is formed next to a bitline structure 200. In some embodiments, the method 20 further includes forming the bitline structure 200 on the substrate 101 and the dielectric layer 102 before performing the operation 21. For a detailed description of the substrate 101 and the dielectric layer 102, please refer to the method 10.

The operation 22 of the method 20 is similar to the operation 12 of the method 10 to form the oxide layer 301O, except that the oxidation process is different. In the operation 22, an upper portion (i.e., the first portion 301A described above) of the first conductive layer is reacted with an oxidizing agent to transform the upper portion of the first conductive layer into the oxide layer 301O. In some embodiments, the oxidizing agent includes a H₂O₂ liquid. In some embodiments, reacting the upper portion of the first conductive layer with the oxidizing agent is performed with a reaction time preferably from 60 seconds to 100 seconds, for example, 60 seconds, 70 seconds, 80 seconds, 90 seconds, or 100 seconds, to obtain a desirable thickness T1 of the oxide layer 301O effectively in a desirable time. In some embodiments, reacting the upper portion of the first conductive layer with the oxidizing agent including immersing the semiconductor structure including the first conductive layer into the oxidizing agent. Therefore, same as the result of the operation 12, after the operation 22, the upper portion is oxidized and the lower portion (i.e., the second portion 301B described above) disposed below the upper portion remains unoxidized.

The operation 23 of the method 20 is substantially the same as the operation 13 of the method 10, in which the nitride layer 302 is formed on the oxide layer 301O and the bitline structure 200. For a detailed description of the operation 23, please refer to the operation 13 of the method 10.

The operation 24 of the method 20 is substantially the same as the operation 14 of the method 10, in which the portion of the nitride layer 302 disposed on the oxide layer 301O and the portion of the oxide layer 301O disposed under the removed portion of the nitride layer 302 are removed. For a detailed description of the operation 24, please refer to the operation 14 of the method 10.

The operation 25 of the method 20 is substantially the same as the operation 15 of the method 10, in which the second conductive layer (i.e., the conductive layer 303 described above) in direct contact with the lower portion of the first conductive layer is formed. For a detailed description of the operation 25, please refer to the operation 15 of the method 10.

The present disclosure also provides a semiconductor structure shown in FIG. 8, which is formed by either the method 10 or the method 20 described above. Therefore, details of the components in the semiconductor structure may not be repeatedly and can be referred to in the description provided above. In some embodiments, the semiconductor structure includes the bitline structures 200 on the substrate 101, a polysilicon layer (i.e., the second portion 301B of the silicon-containing conductive layer 301 described above) between the bitline structures 200, a metal layer (i.e., the conductive layer 303 described above) on the polysilicon layer and between the bitline structures 200, a silicon oxide layer 301O′ (i.e., a remaining portion of the oxide layer 301O after removing the portion of the oxide layer 301O in the operation 14 of the method 10 or the operation 24 of the method 20) on the polysilicon layer and between the metal layer and sidewalls of the bitline structures 200, and the nitride layer 302 on the silicon oxide layer 301O′ and between the metal layer and the sidewalls of the bitline structures 200.

As described above, the design of the silicon oxide layer 301O′ ensures the polysilicon layer (or the second portion 301B of the silicon-containing conductive layer 301) has improved low electrical resistance in the formed semiconductor structure. In some embodiments, the thickness T1 of the silicon oxide layer 301O′ is smaller than 1.5 nm, and, in some embodiments, is preferably from 0.5 nm to 1.5 nm, for example, 0.5 nm, 0.75 nm, 1.0 nm, 1.25 nm, or 1.5 nm. In some embodiments, the silicon oxide layer 301O′ separates the polysilicon layer from the nitride layer 302. In some embodiments, the polysilicon layer includes the P-type dopant or the N-type dopant, as described above, and the dopant concentration of the P-type dopant or the N-type dopant is from 7.5×10²⁰ atoms/cm³ to 7.5×10²¹ atoms/cm³, for example, 7.5×10²⁰ atoms/cm³, 1.0×10²¹ atoms/cm³, 2.5×10²¹ atoms/cm³, 5.0×10²¹ atoms/cm³, or 7.5×10²¹ atoms/cm³. In some embodiments, the foregoing dopant concentration is obtained by measuring the dopant concentration from the topmost surface of the polysilicon layer (or the second portion 301B in the figures) to a depth of around 20 nm. In some embodiments, a width W2 of the nitride layer 302 is substantially the same as a width W1 of the silicon oxide layer 301O′. In some embodiments, the silicon oxide layer 301O′ and the metal layer (or the conductive layer 303) are on a same level above the polysilicon layer. In some embodiments, a bottom surface of the silicon oxide layer 301O′ is aligned with a bottom surface of the metal layer (or the conductive layer 303).

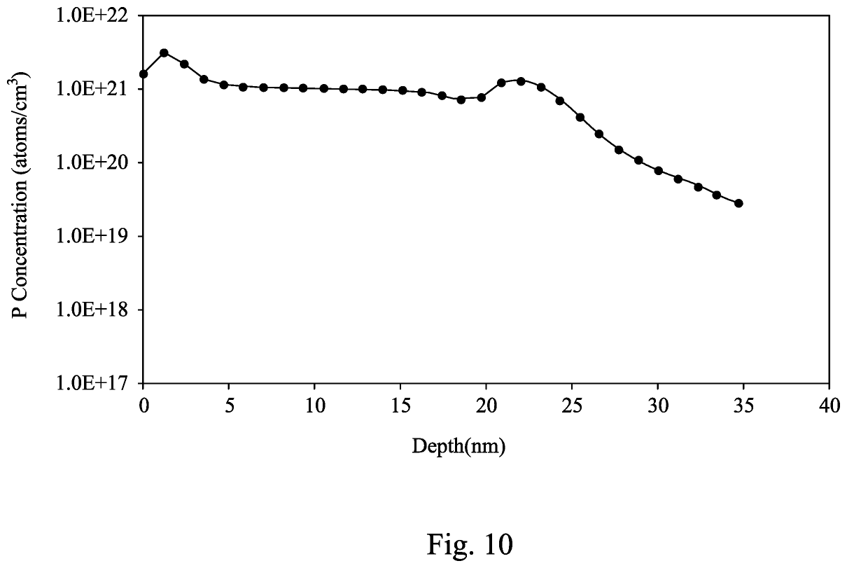

Next, an embodiment is provided for a better understanding of the present application. In this embodiment, a phosphorus dopant is doped into the silicon-containing conductive layer 301 before forming the nitride layer 302, and after forming the nitride layer 302, a phosphorus dopant concentration is measured at different depth of the silicon-containing conductive layer 301, as shown in FIG. 10. By having the oxide layer 301O separating the second portion 301B of the silicon-containing conductive layer 301 and the nitride layer 302, the phosphorus dopant concentration remains high in the second portion 301B of the silicon-containing conductive layer 301, for example, remaining around at least 1.0×10²¹ atoms/cm³ from the topmost surface (i.e., the depth equal to 0 nm in FIG. 10) to the depth of around 20 nm.

The semiconductor structure formed by the methods of the present disclosure has an improved low electrical resistance and can be used in the memory device, such as the dynamic random-access memory.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A method of forming a semiconductor structure, comprising:
forming a silicon-containing conductive layer between bitline structures;
transforming a first portion of the silicon-containing conductive layer into an oxide layer under an ozone environment;
forming a nitride layer on the oxide layer and the bitline structures;
removing a portion of the nitride layer on the oxide layer and a portion of the oxide layer disposed below the portion of the nitride layer; and
forming a conductive layer on a second portion of the silicon-containing conductive layer after removing the portion of the oxide layer.

2. The method of claim 1, wherein after transforming the first portion of the silicon-containing conductive layer into the oxide layer under the ozone environment, a thickness of the oxide layer is smaller than 1.5 nm.

3. The method of claim 1, wherein the oxide layer separates the second portion of the silicon-containing conductive layer from the nitride layer.

4. The method of claim 1, wherein transforming the first portion of the silicon-containing conductive layer into the oxide layer under the ozone environment is performed in an ozone gas with a flow rate from 100 g/cm³ to 200 g/cm³.

5. The method of claim 1, wherein transforming the first portion of the silicon-containing conductive layer into the oxide layer under the ozone environment is performed at a temperature from 250° C. to 300° C.

6. The method of claim 1, wherein transforming the first portion of the silicon-containing conductive layer into the oxide layer under the ozone environment is performed with a processed time from 20 minutes to 30 minutes.

7. The method of claim 1, wherein forming the nitride layer is performed at a temperature from 550° C. to 650° C.

8. The method of claim 1, further comprising doping a P-type dopant or an N-type dopant into the silicon-containing conductive layer before transforming the first portion of the silicon-containing conductive layer into the oxide layer.

9. The method of claim 8, wherein after forming the nitride layer, a dopant concentration in the silicon-containing conductive layer is from 7.5×10²⁰ atoms/cm³ to 7.5×10²¹ atoms/cm³.

10. A method of forming a semiconductor structure, comprising:
forming a first conductive layer next to a bitline structure, wherein the first conductive layer comprises a P-type impurity or an N-type impurity;
reacting an upper portion of the first conductive layer with an oxidizing agent to transform the upper portion into an oxide layer;
forming a nitride layer on the oxide layer and the bitline structure;
removing a portion of the nitride layer on the oxide layer and a portion of the oxide layer disposed below the portion of the nitride layer; and
forming a second conductive layer in direct contact with a lower portion of the first conductive layer.

11. The method of claim 10, wherein after reacting the upper portion of the first conductive layer with the oxidizing agent to transform the upper portion into the oxide layer, a thickness of the oxide layer is smaller than 1.5 nm.

12. The method of claim 10, wherein the oxidizing agent comprises H₂O₂.

13. The method of claim 10, wherein reacting the upper portion of the first conductive layer with the oxidizing agent is performed with a reaction time from 60 seconds to 100 seconds.

14. The method of claim 10, wherein forming the nitride layer is performed at a temperature from 550° C. to 650° C.

15. The method of claim 10, wherein after forming the nitride layer, a concentration of the P-type impurity or the N-type impurity in the first conductive layer is from 7.5×10²⁰ atoms/cm³ to 7.5×10²¹ atoms/cm³.

16. A semiconductor structure, comprising:
a substrate;
bitline structures on the substrate;
a polysilicon layer between the bitline structures;
a metal layer on the polysilicon layer and between the bitline structures;
a silicon oxide layer on the polysilicon layer and between the metal layer and sidewalls of the bitline structures; and
a nitride layer on the silicon oxide layer and between the metal layer and the sidewalls of the bitline structures.

17. The semiconductor structure of claim 16, wherein the silicon oxide layer separates the polysilicon layer from the nitride layer.

18. The semiconductor structure of claim 16, wherein a width of the nitride layer is substantially the same as a width of the silicon oxide layer.

19. The semiconductor structure of claim 16, wherein the polysilicon layer comprises a P-type dopant or an N-type dopant, a dopant concentration of the P-type dopant is from 7.5×10²⁰ atoms/cm³ to 7.5×10²¹ atoms/cm³, and a dopant concentration of the N-type dopant is from 7.5×10²⁰ atoms/cm³ to 7.5×10²¹ atoms/cm³.

20. The semiconductor structure of claim 16, wherein a thickness of the silicon oxide layer is smaller than 1.5 nm.
